(19) United States
(12) Patent Application Publication
(10) Pub. No.: US 2005/0118773 A1
(43) Pub. Date: Jun. 2, 2005

(54) Method of producing an integrated capacitor and a memory field

(76) Inventor: Karlheinz Muller, Waldkraiburg (DE)

Correspondence Address: LERNER AND GREENBERG, PA, P O BOX 2480, HOLLYWOOD, FL, 33022-2480, US

(21) Appl. No.: 11/033,577

(22) Filed: Jan. 12, 2005

Related U.S. Application Data
(62) Division of application No. 08/966,899, filed on Nov. 10, 1997, now abandoned.

(30) Foreign Application Priority Data
Nov. 8, 1996 (DE) 196 46 208.8

(51) Int. Cl. H01L 21/20

(52) U.S. Cl. 438/381

(57) ABSTRACT

A capacitor for an integrated circuit with microstructure has a first and a second electrode separated by a dielectric layer. The dielectric layer is produced during the structuring of the first electrodes by an etching process. The dielectric layer comprises a polymer structure which is formed during the etching process, and/or etching products of the electrode metal. The first electrode may be cylindrical and surrounded by a hollow-cylindrical dielectric layer. The capacitor may be integrated in a memory field with a multiplicity of such capacitors.

### CROSS-REFERENCE TO RELATED APPLICATIONS

This is a divisional application of application Ser. No. 08/966,899, filed Nov. 10, 1997; the application also claims the priority, under 35 U.S.C. §119, of German patent application No. 196 46 208.8, filed Nov. 8, 1996; the prior applications are herewith incorporated by reference in their entirety.

### BACKGROUND OF THE INVENTION

### FIELD OF THE INVENTION

The invention relates to an integratable capacitor with a dielectric layer and two electrodes, of the kind used particularly in integrated circuits with microstructures, and to a method for its production, as well as to a memory field in which the novel capacitors are used.

Capacitors are typically embodied in integrated circuits in a planar, trenched, or stacked configuration. Such capacitors are used in combination with a transistor to form memory cells in semiconductor memories. In that case, a multiplicity of memory cells are disposed in one memory field.

The pertinent art produces the dielectric layer located between the electrically conductive electrode materials of such capacitors from SiO₂ or Si₃N₄, for instance. While such a dielectric layer does exhibit favorable electrical properties, such as a high degree of insulation and a high dielectric constant, its production is quite complicated and always requires at least one additional production step. This is due to the fact that, after the production of the electrode, the dielectric layer is applied to the surface thereof.

### SUMMARY OF THE INVENTION

It is accordingly an object of the invention to provide an integratable capacitor, production method, and a memory field in which the novel capacitor is used, which overcome the above-mentioned disadvantages of the prior art devices and methods of this general type and which provides for a particularly simply production of a capacitor with a dielectric layer and two electrodes—particularly for use in integrated circuits with a microstructure—and which has a dielectric layer with good electrical properties.

With the foregoing and other objects in view there is provided, in accordance with the invention, a capacitor, comprising:
a first electrode etched from a metal layer, a second electrode, and a dielectric layer disposed between said first electrode and said second electrode;
said dielectric layer having a material formed upon etching said first electrode, such as a polymer structure formed upon etching of said metal layer and/or etching products of the metal formed upon etching of the metal layer.

For structured surfaces in integrated circuits, etching methods are typically used. A survey of suitable etching methods can be found for instance in D. Widmann, H. Mader and H. Friedrich, Technologie hochintegrierter Schaltungen [LSI Circuit Technology], Second Edition, Springer-Verlag, Berlin, 1996 and K. Schade, Mikroelektroniktechnologie [Microelectronics], first edition, Verlag-Technik, Berlin, 1991. Those teachings are herein incorporated by reference.

To etch electrodes out of a metal layer, a photoresist mask is for instance applied to the metal layer, covering those regions that are not to be etched—that is, what will later be the electrodes. The etching operation itself is preferably a dry etching process, with anisotropic etching. The surfaces of the electrodes laid bare by the etching are seldom pure metal surfaces. On the contrary, they have deposits of etching products that until now were removed completely, to obtain metal surfaces, before the further processing of the electrodes. Over these metal surfaces, a dielectric layer of silicon dioxide, silicon nitride or the like was then applied in order to produce capacitors.

According to the invention, however, the etching operation is performed such that when an electrode is etched out of a metal layer, a continuous dielectric layer is purposefully formed over the surfaces of the electrode accessible to the etchant, and this dielectric layer can act directly as the dielectric in a capacitor. The novel dielectric layer comprises etching products of the metal and/or polymer structures that form during the etching operation and are deposited on the electrode surface.

As the etching method, chemical or physical-chemical dry etching processes are preferably used, of the kind described in principle in the above-mentioned literature. In accordance with a particularly suitable mode of the invention, the etching process is plasma etching.

The etchant, which is preferably an etching gas, is chosen in dependence on the structure to be etched and in particular on the metal layer to be etched. Those skilled in the pertinent art will choose the most suitable etchants for each particular application. Suitable etchants may be selected, for instance, from the above-mentioned literature.

In accordance with an additional feature of the invention, the metal layers to be etched may for instance substantially comprise aluminum or tungsten. In the case of aluminum, etchants containing fluorine are unfavorable, because they form etching products with poor volatility.

Fundamentally suitable etchants are such halogens as F₂, Cl₂, Br₂, I₂; hydrogen halides such as HF, HCl, HBr, HI; halogen compounds of boron, silicon or antimony; or halogenated hydrocarbons. In each case, either a single compound or a plurality of compounds of each of these groups may be used, or mixtures of a plurality of compounds of the various groups. Moreover, the etchants may contain additives of other typically used compounds, such as nonhalogenated hydrocarbons.

If carbon-containing compounds and in particular halogenated hydrocarbons, optionally in combination with other compounds typically used in etching, are used as the etching gas, then polymer structures form on the surface of the etched metal layer during the etching operation. In the case of halogenated hydrocarbons, these structures for instance comprise halogenated carbon chains. Other etching products that are formed in the course of the etching method may be halides or oxides of the etched metal, for instance.

In the production of the capacitors of the invention, the etching method is performed such that over the etched surfaces of the first electrode, which is etched out of a metal layer, a continuous dielectric layer is purposefully created, which comprises a polymer structure and/or etching products of the metal.

The composition of the layer and thus both its physical-chemical properties and its layer thickness are determined by a suitable choice of etchant and of the method parameters during etching. In this way, a very simple and purposeful production of the dielectric layer between a first and a second electrode in a capacitor is possible.

In accordance with another feature of the invention, the first electrode is cylindrical, and the dielectric layer is hollow-cylindrical and envelopes the cylinder jacket. The cylindrical electrode is expediently produced by an anisotropic etching process, in which virtually vertical side regions of the structured surfaces are created. The cylinder axis extends at right angles to the surface of the base structure over which the metal layer to be etched was disposed. In this configuration, the dielectric layer is simple to produce, and an advantageous arrangement of the capacitor is achieved. The novel structure is distinguished by good contactability and it requires little space. The second electrode is formed around the dielectric layer.

If the capacitors are integrated in a memory field with many first electrodes, the second electrode may be a metal layer that serves as a common counter-electrode to a plurality or all of the first electrodes.

Advantageously, the contacting points are disposed on the ends of the electrodes with regard to the cylinder axes. This configuration produces an advantageous layout of the leads contacting the capacitor(s).

In accordance with a further feature of the invention, short circuits between the electrodes are prevented in that the height of the second electrode is less than the height of the first electrode. This can be accomplished for instance by removing the second electrode so far that its top is located at a lower level than the top of the first electrode. Expediently, the second electrode is removed by grinding or etching.

In accordance with yet a further feature of the invention, a conductive layer is disposed on the top of the second electrode. In one embodiment of the invention, the conductive layer comprises a metal silicide, such as MoSi₂, WSi₂, TaSi₂, or TiSi₂. In accordance with an advantageous feature, the electrically conductive layer has a lower resistance than the second electrode.

In accordance with yet another feature of the invention, a further conductive layer is disposed over the first-mentioned conductive layer. The further layer has low impedance and may be formed of a metal such as aluminum or copper. The lower electrically conductive layer acts as a barrier layer for the upper conductive layer. The layer structure with different resistances is equivalent in principle to a configuration with parallel-connected resistors.

In accordance with an advantageous further feature of the invention, the height of the second electrode plus the conductive layer, and optionally the further conductive layer, is less than the height of the first electrode.

With the above and other objects in view there is provided, in accordance with the invention, a suitable method of producing a capacitor with a first electrode, a second electrode, and a dielectric layer between the first and second electrodes. The novel method comprises the following steps:
forming a metal layer on a base structure;
etching the metal layer and thereby producing a first electrode and, on a surface of the first electrode which is accessible to etching, a dielectric layer formed of a polymer structure and/or etching products of the metal layer;
forming a second electrode such that the first electrode and the second electrode are separated from one another by the dielectric layer.

In other words, a metal layer is first applied over a base structure. The base structure may for instance be a conductor track system. The metal layer is etched in such a way that a first electrode is created, and on the surface thereof which is accessible to etching, a polymer structure and/or etching products of the metal are formed as a dielectric layer.

Next, a second electrode is applied in such a way that the first and second electrodes are separated from one another by the dielectric layer.

The novel method thus only comprises three steps, namely the etching of the metal layer, the formation of a dielectric layer on the etched surfaces of the metal layer, and the disposition of the second electrode adjacent the dielectric layer. The production of the capacitor in only three steps saves considerable time and expense.

Suitable etching methods and etchants have already been described at the outset.

The metal layer is advantageously etched anisotropically, and the dielectric layer is created at the vertical flanks of the first electrode.

The aforementioned method steps can expediently be followed by an anisotropic back-etching or back-grinding of the second electrode; the metal layer of the second electrode is etched deeper than the first, so as reliably to avoid a short circuit to the first electrode. Moreover, at least one electrically conductive layer may be applied over the second electrode.

If an additional conductive layer is applied over the conductive layer, then the additional layer is in turn expediently back-etched or ground back until such time as the contact with the higher first electrode is broken. By means of the electrically conductive layers, contacting of electrodes can be achieved in a very simple way. If the electrically conductive layers extend over a plurality of electrodes, then in a simple way an electrical connection between these capacitor electrodes can be realized.

The method of the invention is suitable not only for producing individual capacitors but also and in particular for simultaneously producing a plurality of capacitors according to the invention, which by way of example are mounted in a memory field that comprises a plurality of capacitors, disposed side by side, along with further conventional components.

Accordingly, with the above and other objects in view there is also provided, in accordance with the invention, a memory field which comprises: a plurality of capacitors disposed side by side, each of the capacitors including a first electrode etched from a metal layer, a second electrode, and a dielectric layer disposed between the first electrode and the second electrode, where the material of the dielectric layer is formed upon etching the first electrode. As used herein, such material is a polymer structure formed upon etching the metal layer and/or etching products of the metal formed upon etching of the metal layer.

The second electrode, which is expediently a metal layer serving as a counter electrode to a plurality of first electrodes, is advantageously contacted by forming a lead region by increasing the spacing between adjacent first electrodes, so as to create enough space for the base point of a bonding wire.

Other features which are considered as characteristic for the invention are set forth in the appended claims.

Although the invention is illustrated and described herein as embodied in an integratable capacitor, method for its production, and memory field using the capacitor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a sectional view taken through an integrated circuit before first electrodes have been etched;

FIG. 2 is a sectional view of an integrated circuit with the first electrodes etched and with the dielectric layers according to the invention;

FIG. 3 is a sectional view of an integrated circuit with a metal layer applied for producing the second electrode;

FIG. 4 is a sectional view of an integrated circuit with capacitors according to the invention;

FIG. 5 is a plan view on an integrated circuit with capacitors according to the invention;

FIG. 6 is a plan view on an integrated circuit with the capacitors and with a terminal field; and

FIG. 7 is a sectional view taken along the line A-A of FIG. 6 and viewed in the direction of the arrows.

### DESCRIPTION OF THE PREFERRED EMBODIMENTS

Referring now to the figures of the drawing in detail, there is seen an integrated circuit in the form of a configuration of a multiplicity of capacitors forming a memory field. Transistors are disposed below the capacitors. However, the transistors are not illustrated for purposes of clarity in the drawing.

The production of an integrated circuit having a microstructure with capacitors according to the invention will now be described in the sequence of the drawing figures.

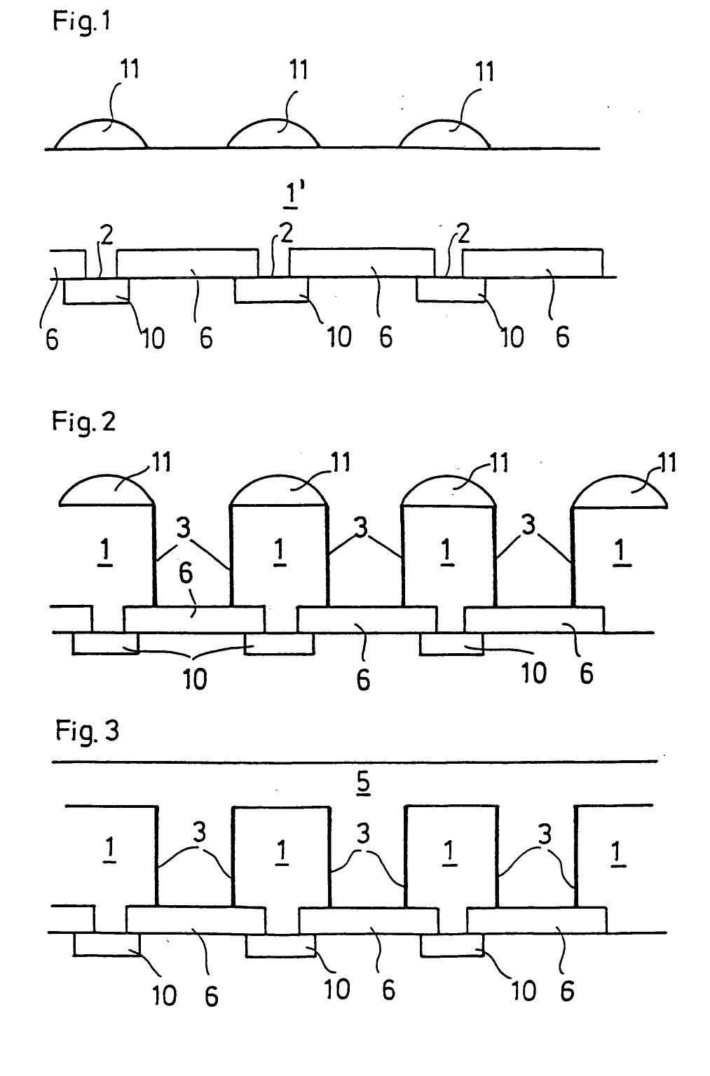

With reference to FIG. 1, the conductor tracks 10 form the base structure of an integrated circuit. Other, non-illustrated components, such as transistors and other conductor tracks, are located beneath the conductor tracks 10. There are three conductor tracks 10, spaced apart uniformly from one another and side by side. Above, forming the next structure, there is disposed one dielectric layer 6 in each of the regions between the conductor tracks 10. This will hereafter be referred to as the base structure dielectric 6. A metal layer 1′ is disposed over it. Since the base structure dielectric 6 is disposed only in the interstices between the conductor tracks 10, the metal layer 1′ extends between them as far as the conductor tracks 10. An electrical contact takes place in these regions 2. The metal layer is relatively high (tall) and it is flat on its surface. A resist 11 of a resist mask is aligned precisely above the contact regions 2 between the metal layer 1′ and the conductor tracks 10.

FIG. 2 shows the next intermediate processing stage in the production process. The surface of the metal layer 1′ has been etched anisotropically, and the regions of the surface provided with the resist 11 have been removed by the etching operation. In the stage shown in FIG. 2, the metal layer 1′ has been etched down to the base structure dielectric 6. In this way, individual first electrodes 1 have been created from the metal layer 1′. On its sides, the etching operation has formed a dielectric layer 3, which has been created purposefully in terms of its composition and layer thickness by a suitable choice of the etching gas and of the method parameters during the etching.

In the ensuing steps, the resist 11 is removed, and a further metal layer 5 is applied to the integrated circuit structure. As FIG. 3 shows, this metal layer 5 is high enough that it protrudes past the height of the electrodes 1. It has a flat surface.

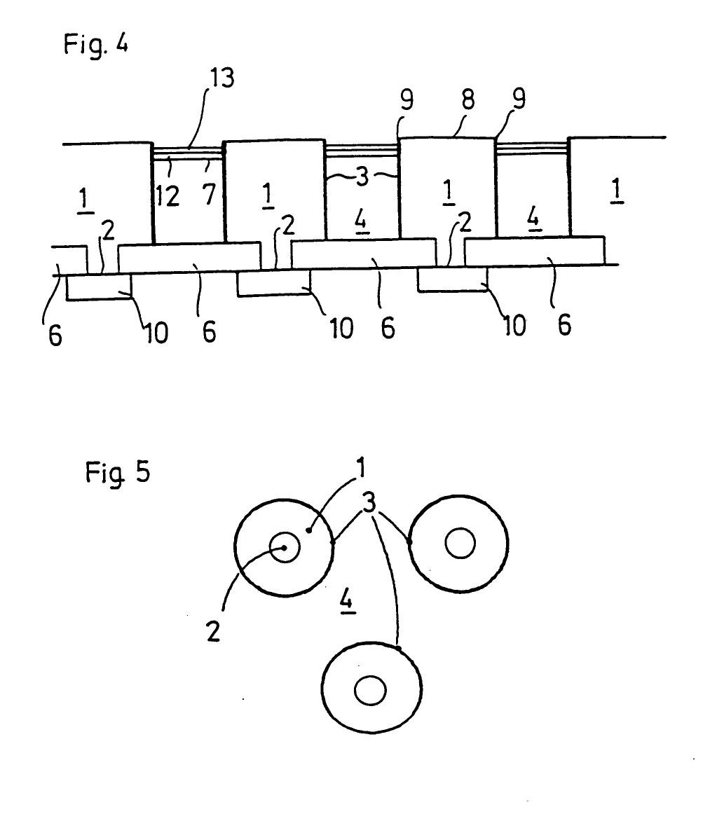

FIG. 4 illustrates the further course of a method, in which the metal layer 5 is back-etched far enough that its surface 7 is located below the surfaces 8 of the first electrodes 1. This lays bare an upper end 9 of the dielectric layer 3. By the back-etching of the metal layer 5 (e.g. tungsten) as described, a second electrode 4 is obtained, which acts as a common counter-electrode for a plurality of first electrodes 1. A thin silicide layer 12 is applied as an electrically conductive layer to the surface 7 of the second electrode 4. A second, low-impedance, electrically conductive layer 13 is formed on the silicide layer 12. The layer 13 has been removed in a way similar to the metal layer 5 in an anisotropic etching method from the surfaces 8 of the first electrode 1 and extends only over the regions 12 of the second electrode 4 that have been provided with silicide. The barrier layer 12 and the layer 13 have a substantially lower resistance than the metal layer of the second electrode 4. These two layers can be thought of as a parallel circuit of resistors.

As FIG. 5 shows, in the embodiment the capacitors formed of the electrodes 1 and 4 and the dielectric layer 3 are disposed in an ordered configuration.

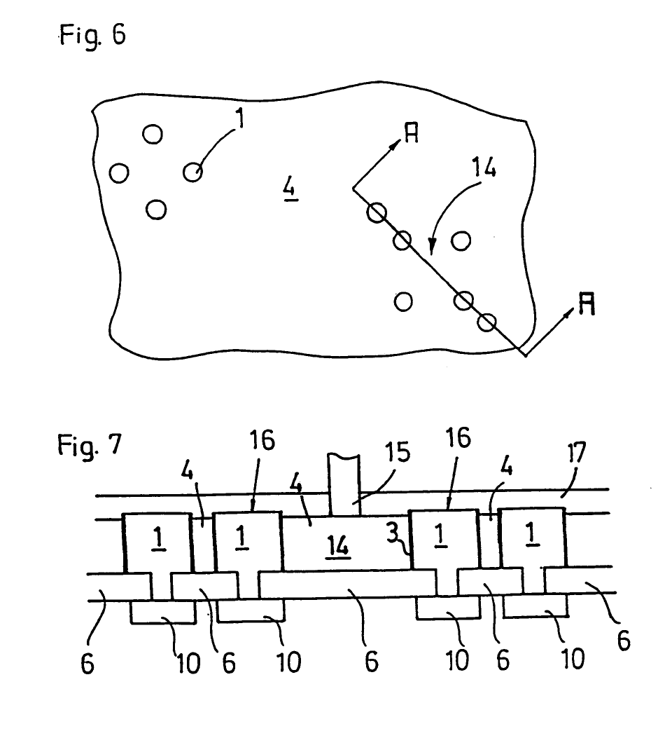

FIG. 6 shows the plan view on a system of a plurality of capacitors. In the region marked 14, the adjacent capacitors have an increased spacing from one another and form a lead field or terminal field. In this lead field 14, a contact with the second electrode 4 of the capacitors can be made, for instance by a bonding process.

FIG. 7 illustrates one possible way of contacting the second electrode 4. The contacting is effected by producing a bond connection in the lead field 14. The bonding wire 15 is fixed in the lead field 14, which has a larger surface area than the intermediate region between two normally spaced-apart electrodes 1. A dielectric layer 17, embodied as an IMOX (intermetal oxide) is applied over this configuration. The lead field 14 may be thought of as a kind of pad window for the bonding wire 15, or for a VIA for the next metal plane.

1. A method for producing a capacitor having a first electrode produced by etching of a metal layer, a second electrode, and a dielectric layer between the first electrode and the second electrode, which method comprises:
covering the metal layer with a mask formed from lacquer or photoresist;
anisotropically etching the first electrode with an etching process selected from the group consisting of chemical or chemical-physical dry etching and plasma etching to form structured etching products from the metal of the metal layer and an etching gas, the etching products consisting of the metal and/or a polymer, being disposed at a surface being accessible to the etching and not being covered by the mask, and forming the dielectric layer.

2. The method according to claim 1, which comprises etching the first electrode from a metal layer essentially consisting of a metal selected from the group consisting of tungsten, aluminum, and copper.

3. The method according to claim 1, which comprises etching with an etching gas selected from the group consisting of a gas including one or more halogenated hydrocarbons, one or more halogens, one or more hydrogen halides, one or more halogen compounds of boron, silicon or antimony, or mixtures of these compounds.

4. The method according to claim 1, which comprises forming the dielectric layer on vertical flanks of the first electrode.

5. The method according to claim 1, which comprises forming the second electrode as a metal layer around the first electrode and the dielectric layer.

6. The method according to claim 5, which comprises removing part of the second electrode so far that a height thereof is less than a height of the first electrode.

7. The method according to claim 6, which comprises forming at least one electrically conductive layer on the second electrode and removing part of the electrically conductive layer so that a height of the second electrode and the electrically conductive layer is less than a height of the first electrode.

8. A method for producing a plurality of capacitors for a memory field, which comprises producing each of the plurality of capacitors according to the method of claim 1 and thereby disposing the capacitors adjacent one another, and forming the second electrodes as a metal layer serving as a common counter-electrode to the first electrodes of the memory field.

9. The method according to claim 8, which comprises forming a lead field by increasing a spacing between adjacent capacitors, and firmly bonding in the lead field a bonding wire for contacting the memory field or for contacting the next metallizing layer.

10. A method for producing a capacitor, which comprises:
providing a metal layer on a substrate;
covering the metal layer with a mask formed from lacquer or photoresist;
anisotropically etching the first electrode with an etching process selected from the group consisting of chemical or chemical-physical dry etching and plasma etching to form a dielectric layer at a surface that is accessible to the etching and is not covered by the mask, the dielectric layer being formed from the metal of the metal layer and an etching gas, and an etching product consisting of at least one of the metal and a polymer; and
forming a second electrode on the dielectric layer.
